(19) United States
(12) Patent Application Publication
(10) Pub. No.: US 2010/0167467 A1
(43) Pub. Date: Jul. 1, 2010

(54) METHOD FOR FABRICATING SEMICONDUCTOR DEVICE

(75) Inventor: Nobuo AOI, Hyogo (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/721,038

(22) Filed: Mar. 10, 2010

Related U.S. Application Data
(63) Continuation of application No. PCT/JP2009/003165, filed on Jul. 7, 2009.

(30) Foreign Application Priority Data
Sep. 26, 2008 (JP) 2008-248684

(51) Int. Cl. H01L 21/822; H01L 21/78

(52) U.S. Cl. 438/109; 438/113; 257/E21.599; 257/E21.614

(57) ABSTRACT

At least three or more plurality of chips are stacked to form a three-dimensional integrated circuit. When the plurality of chips are stacked, at least two or more of three stacking methods are used which are a wafer-to-wafer stacking method that bonds together the mutually corresponding chips each on a wafer level, a chip-to-wafer stacking method that bonds together the mutually corresponding chips including one on a chip level and the other on a wafer level, and a chip-to-chip stacking method that bonds together the mutually corresponding chips each on a chip level.

### CROSS-REFERENCE TO RELATED APPLICATION

This is a continuation of PCT International Application PCT/JP2009/003165 filed on Jul. 7, 2009, which claims priority to Japanese Patent Application No. 2008-248684 filed on Sep. 26, 2008. The disclosures of these applications including the specifications, the drawings, and the claims are hereby incorporated by reference in its entirety.

### BACKGROUND

The present disclosure relates to a method for fabricating a semiconductor device, and particularly to a method for fabricating a three-dimensional integrated circuit element using a mounting method called “system in package (SiP)”.

In a mounting method called “system in package (SiP)”, a technique for integrating various chip stacks into one package has been used practically. In the SiP method, the chip stacks are formed by a chip-to-chip stacking method which bonds together mutually corresponding chips each on a chip level. For a connection between chips and a connection between chip stacks, a method has been adopted which provides an electric connection using flip-chip, wire bonding, an interposer, or the like (see, e.g., ITRS 2007 Assembly & Package Chapter, pp. 35-37).

### SUMMARY

However, in a semiconductor device having a chip stack using wire bonding, wires cause an increase in package area, as shown in FIG. 8A. In a semiconductor device 10 shown in FIG. 8A, a logic chip 12, an interface chip 13, and a memory chip 14 are successively stacked on the top surface of an interposer 11, and wires 15 are provided so as to connect the individual chips 12-14 and the interposer 11. Note that a resin 16 is formed so as to mold a stack of the chips 12-14 and the wires 15 over the top surface of the interposer 11. On the back surface of the interposer 11, there are formed a plurality of external terminals 17.

In a semiconductor device using flip-chip also, a plurality of chips are two-dimensionally placed over an interposer or over a device chip, as shown in FIG. 8B, so that an increase in package area is inevitable. In a semiconductor device 20 shown in FIG. 8B, a logic chip 22, an interface chip 23, and a memory chip 24 are two-dimensionally arranged on the top surface of an interposer 21 and flip-chip connected, while on the back surface of the interposer 21, a plurality of external terminals 27 are formed.

In a conventional SiP method, when chip stacks are needed in order to integrate individual single-element chips into one package, it is necessary to repeatedly implement a chip-to-chip stacking method a plurality of times so that a problem of reduced throughput, increased cost, or the like arises.

Additionally, in the conventional SiP integration method which repeatedly implements the chip-to-chip stacking method a plurality of times, the accuracy of alignment between the individual chips is low so that it is difficult to provide high-density chip-to-chip connections. Specifically, a placement pitch for wire bonding pads and flip-chip electrodes can be reduced only to about 30 μm at minimum.

In view of the foregoing, an object of the present disclosure is to enable, when chips are electrically connected to each other and stacked to be packaged, high-accuracy stacking of chips to be implemented by a simple and easy process, while inhibiting a package area and a package size from being increased.

To attain the object, a first method for fabricating a semiconductor device according to the present disclosure is a method for fabricating a semiconductor device having a three-dimensional integrated circuit formed by stacking at least three or more plurality of chips, including the step of: stacking the plurality of chips using at least two or more of three stacking methods which are a wafer-to-wafer stacking method that bonds together the mutually corresponding chips each on a wafer level, a chip-to-wafer stacking method that bonds together the mutually corresponding chips including one on a chip level and the other on a wafer level, and a chip-to-chip stacking method that bonds together the mutually corresponding chips each on a chip level.

That is, in the formation of a chip stack, the first method for fabricating a semiconductor device according to the present disclosure inevitably uses at least one of the wafer-to-wafer stacking method that bonds together the mutually corresponding chips each on a wafer level and the chip-to-wafer stacking method that bonds together the mutually corresponding chips including one on a chip level and the other on a wafer level.

In the first method for fabricating a semiconductor device according to the present disclosure, when the mutually corresponding chips are bonded together using the wafer-to-wafer stacking method, the chip-to-wafer stacking method, or the chip-to-chip stacking method, the both chips may be electrically connected to each other with a through-silicon-via.

A second method for fabricating a semiconductor device according to the present disclosure includes the steps of: (a) stacking a plurality of first wafers each provided with a plurality of memory chips so as to electrically connect the mutually corresponding memory chips to each other with first through-silicon-vias to form a wafer stack; (b) dividing the wafer stack by dicing to form a plurality of first chip-to-chip stacks; (c) stacking the plurality of first chip-to-chip stacks and a second wafer provided with a plurality of interface chips so as to electrically connect the first chip-to-chip stacks and the interface chips, which correspond to each other, with second through-silicon-vias to form a first chip-to-wafer stack; (d) dividing the first chip-to-wafer stack by dicing to form a plurality of second chip-to-chip stacks; (e) stacking the plurality of second chip-to-chip stacks and a third wafer provided with a plurality of logic chips so as to electrically connect the second chip-to-chip stacks and the logic chips, which correspond to each other, via third through-silicon-vias to form a second chip-to-wafer stack; and (f) dividing the second chip-to-wafer stack by dicing to form a plurality of third chip-to-chip stacks.

In the second method for fabricating a semiconductor device according to the present disclosure, the step (b) may include the step of fixing the wafer stack onto a support substrate, and dicing the wafer stack, and the step (c) may include the step of forming the first chip-to-wafer stack, and then stripping the support substrate from the first chip-to-wafer stack.

The second method for fabricating a semiconductor device according to the present disclosure may further includes, between the steps (c) and (d), the step of: polishing the back surface of the second wafer of the first chip-to-wafer stack (i.e., the surface on which the first chip-to-chip stack is not formed) to thin the second wafer.

In the second method for fabricating a semiconductor device according to the present disclosure, the first through-silicon-vias, the second through-silicon-vias, and the third through-silicon-vias may be each formed of a conductive material containing copper as a main component.

The second method for fabricating a semiconductor device according to the present disclosure may further includes, after the step (f), the step of: (g) stacking each of the plurality of third chip-to-chip stacks and each of a plurality of other chips to form a plurality of fourth chip-to-chip stacks.

According to the present disclosure, a plurality of chips are electrically connected to each other with the through-silicon-vias and stacked. Accordingly, compared with the case where an electrical connection is provided using flip-chip, wire bonding, or the like, increases in package area and package size can be reduced. Additionally, in the formation of the chip stack, at least one of the wafer-to-wafer stacking method that bonds together the mutually corresponding chips each on a wafer level and the chip-to-wafer stacking method that bonds together the mutually corresponding chips including one on a chip level and the other on a wafer level is used. Therefore, it is possible to implement high-accuracy stacking of the chips by a simple and easy process.

As described above, the method for fabricating a semiconductor device according to the present disclosure enables, when the chips are electrically connected to each other and stacked to be packaged, high-accuracy stacking of the chips to be implemented by a simple and easy process, while inhibiting a package area and a package size from being increased. In particular, the method for fabricating a semiconductor device according to the present disclosure is useful as a method for fabricating a three-dimensional integrated circuit element using a mounting method called “system-in-package”.

### BRIEF DESCRIPTION OF THE DRAWINGS

FIG. 1 is a cross-sectional view showing an example of a semiconductor device according to an example embodiment of the present disclosure.

FIGS. 2A-2H are views showing the individual steps of a method for fabricating the semiconductor device according to the example embodiment of the present disclosure.

FIG. 3 is a perspective view schematically showing a plurality of wafers stacked in the step shown in FIG. 2A.

FIG. 4 is a cross-sectional view showing details of chip-to-chip connections in memory chip stacks formed in the step shown in FIG. 2C.

FIG. 5 is a cross-sectional view showing details of a chip-to-wafer connection in a chip-to-wafer stack formed in the step shown in FIG. 2G.

FIGS. 6A and 6B are views showing the individual steps of a method for fabricating a semiconductor device according to a variation of the example embodiment of the present disclosure.

FIG. 7 is a cross-sectional view showing details of a chip-to-chip connection in a chip-to-chip stack formed in the step shown in FIG. 6B.

FIG. 8A is a cross-sectional view showing a conventional semiconductor device having a chip stack using wire bonding, and FIG. 8B is a cross-sectional view showing a conventional semiconductor device using flip-chip.

### DETAILED DESCRIPTION

### Example Embodiment

Referring to the drawings, a semiconductor device and a method for fabricating the same according to an example embodiment of the present disclosure will be described specifically below. Note that, in the present example embodiment, a method for stacking a dynamic random access memory (DRAM) and a logic large scale integration (LSI) will be described as an example.

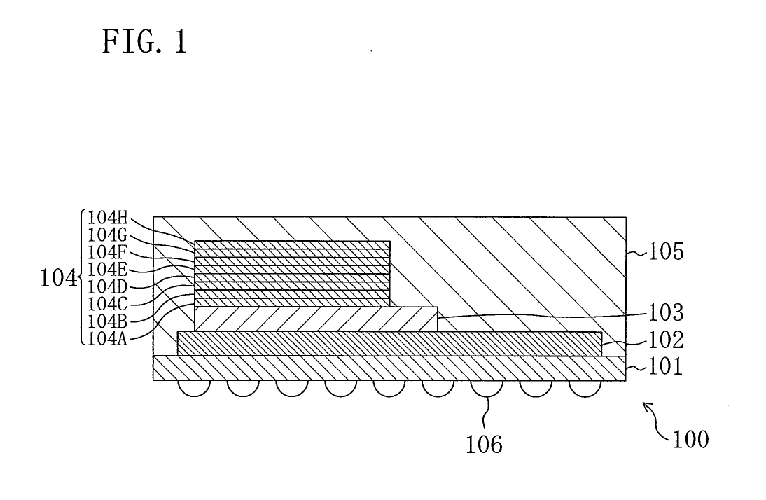

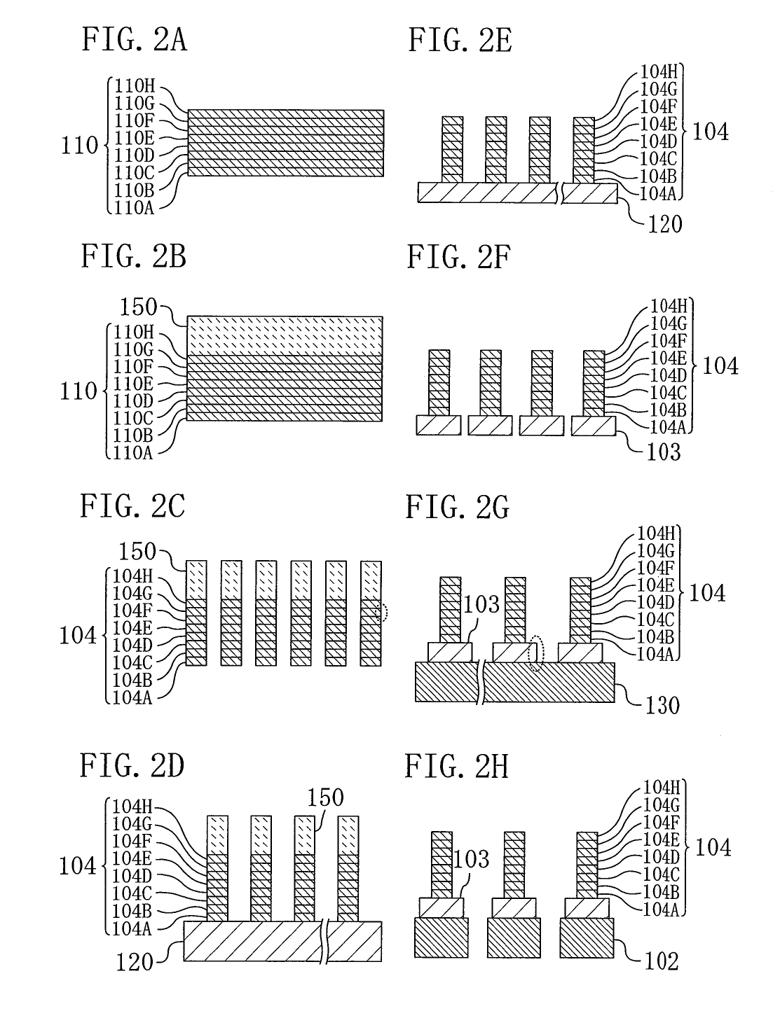

FIG. 1 is a cross-sectional view showing an example of a semiconductor device according to the present example embodiment, specifically a semiconductor device formed by the method for fabricating a semiconductor device according to the present disclosure. In a semiconductor device 100 shown in FIG. 1, on the top surface of an interposer 101, there are successively stacked a logic chip 102, an interface chip 103, and a memory chip stack 104. The memory chip stack 104 is formed by bonding together a plurality of (e.g., eight) memory chips 104A-104H, and stacking the memory chips 104A-104H. The individual chips are electrically connected with through-silicon-vias not shown. Note that a resin 105 is formed so as to mold the logic chip 102, the interface chip 103, and the memory chip stack 104 over the top surface of the interposer 101. On the back surface of the interposer 101, a plurality of external terminals 106 are formed. FIGS. 2A-2H are views showing the individual steps of the method for fabricating the semiconductor device according to the present example embodiment.

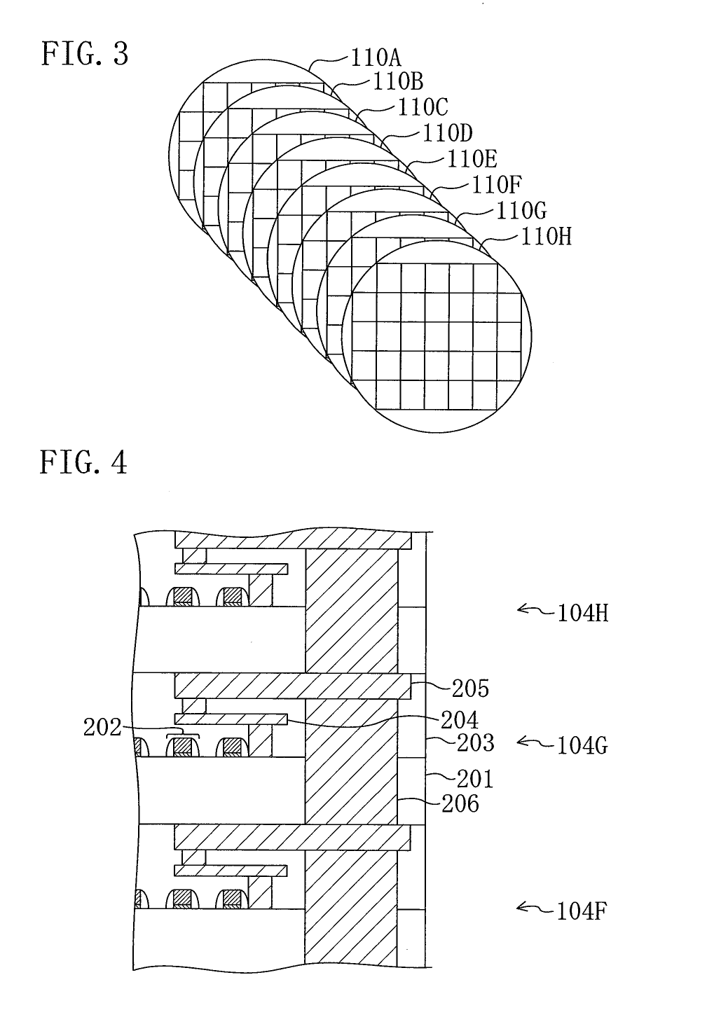

First, as shown in FIG. 2A, a plurality of (e.g., eight) first wafers 110A-110H having a plurality of memory chips mounted thereon are stacked each on a wafer level (i.e., using a wafer-to-wafer stacking method) such that the mutually corresponding memory chips are electrically connected to each other with the through-silicon-vias. Here, in the stacking of the first wafers 110A-110H, the through-silicon-vias (each containing, e.g., copper as a main component) of the mutually corresponding memory chips are connected to each other by thermocompression. As a result, the mutually corresponding memory chips of the eight stacked first wafers 110A-110H are electrically connected to each other. FIG. 3 is a perspective view diagrammatically showing the eight first wafers 110A-110H.

Next, as shown in FIG. 2B, the surface of the first wafer 110H of a stack of the plurality of first wafers 110A-110H is fixed onto a glass support substrate 150.

Next, as shown in FIG. 2C, the stack of the plurality of first wafers 110A-110H is divided into the individual chips by dicing, while the wafer stack is fixed onto the glass support substrate 150. In this manner, the memory chip stacks 104 in each of which the plurality of (e.g., eight) memory chips 104A-104H are bonded together are respectively formed on a plurality of the glass support substrates 150 resulting from the division of the glass support substrate 150 into individual chip sizes.

FIG. 4 is a cross-sectional view showing details of chip-to-chip connections in each of the memory chip stacks 104. As shown in FIG. 4, in each of the memory chips 104A-104H, gate electrode structures 202 are formed on a substrate 201 made of, e.g., silicon. In addition, an interlayer insulating film 203 is formed so as to cover the gate electrode structures 202. In the interlayer insulating film 203, formed is a multilayer interconnection 204 and, in a surface portion of the interlayer insulating film 203, formed is an electrode terminal 205 connected to the multilayer interconnection 204. In the substrate 201 and the interlayer insulating film 203, formed is a through-silicon-via 206 having one end connected to the electrode terminal 205 and the other end reaching the back surface of the substrate 201. By the connection of the other end of the through-silicon-via 206 exposed at the back surface of the substrate 201 to the electrode terminal 205 of another memory chip located under the memory chip having the through-silicon-via 206, a chip-to-chip electrical connection is provided.

Next, as shown in FIG. 2D, the plurality of memory chip stacks 104 respectively fixed onto the plurality of glass support substrates 150 and a second wafer 120 having a plurality of interface chips mounted thereon are bonded together by a chip-to-wafer stacking method using, e.g., a die bonder. At this time, the memory chip stacks 104 (precisely the memory chips 104A of the memory chip stacks 104) and the interface chips, which correspond to each other, are electrically connected with through-silicon-vias. Note that, in each of the interface chips mounted on the second wafer 120, the through-silicon-via (containing, e.g., copper as a main component) has been formed in advance.

Next, as shown in FIG. 2E, the glass support substrate 150 bonded to each of the memory chip stacks 104 is stripped from a chip-to-wafer stack formed in the step shown in FIG. 2D, and the back surface (on which the memory chip stacks 104 are not formed) of the second wafer 120 of the chip-to-wafer stack is polished to thin the second wafer 120.

Next, as shown in FIG. 2F, the chip-to-wafer stack in which the plurality of memory chip stacks 104 and the second wafer 120 are stacked is divided into the individual chips by dicing. As a result, a plurality of chip-to-chip stacks are formed in which the plurality of memory chip stacks 104 and the plurality of interface chips 103 resulting from the division of the second wafer 120 are stacked.

Next, as shown in FIG. 2G, the plurality of chip-to-chip stacks formed in the step shown in FIG. 2F and a third wafer 130 having a plurality of logic chips mounted thereon are bonded together by the chip-to-wafer stacking method. At this time, the chip-to-chip stacks (precisely the interface chips 103 of the chip-to-chip stacks) and the logic chips, which correspond to each other, are electrically connected to each other with through-silicon-vias. Note that, in each of the logic chips mounted on the third wafer 130, the through-silicon-via (containing, e.g., copper as a main component) has been formed in advance.

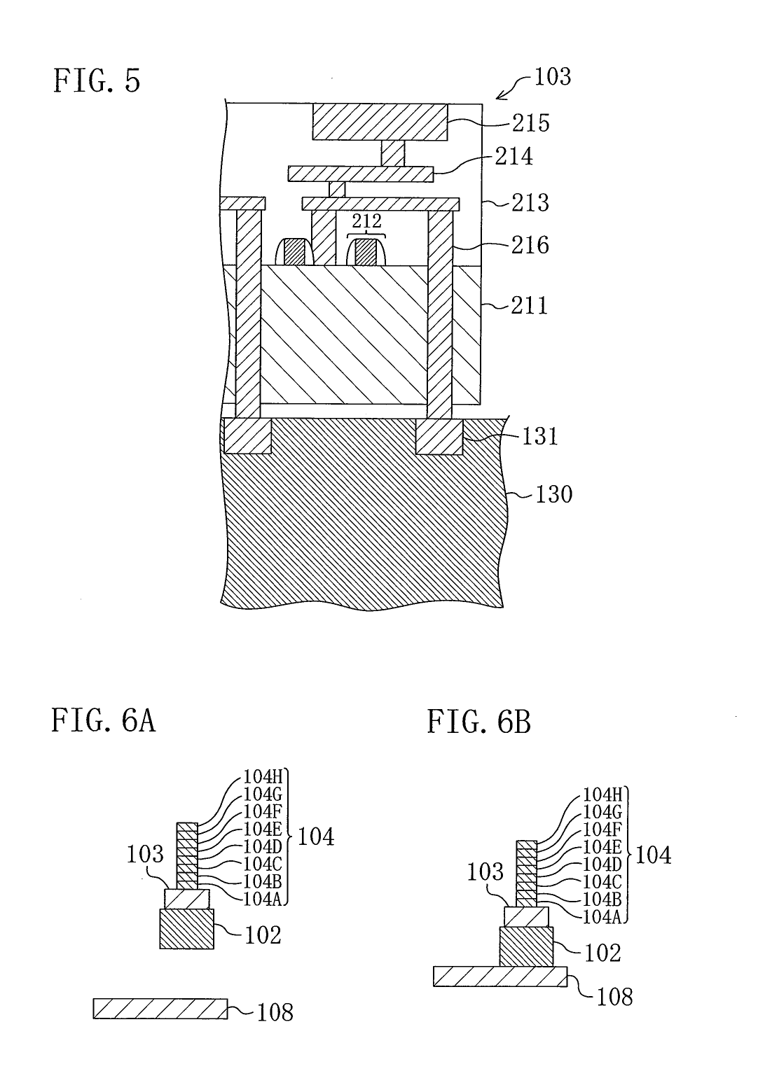

FIG. 5 is a cross-sectional view showing details of a chip-to-wafer connection in a chip-to-wafer stack formed in the step shown in FIG. 2G. As shown in FIG. 5, in each of the interface chips 103, gate electrode structures 212 are formed on a substrate 211 made of, e.g., silicon. In addition, an interlayer insulating film 213 is formed so as to cover the gate electrode structures 212. In the interlayer insulating film 213, formed is a multilayer interconnection 214 and, in a surface portion of the interlayer insulating film 213, formed is an electrode terminal 215 connected to the multilayer interconnection 214. In the substrate 211 and the interlayer insulating film 213, formed is a through-silicon-via 216 having one terminal connected to the multilayer interconnection 214 and the other terminal reaching the back surface of the substrate 211. By the connection of the other end of the through-silicon-via 216 exposed at the back surface of the substrate 211 to the corresponding one of electrode terminals 131 formed in a surface portion of the third wafer 130 (i.e., the logic chips mounted on the third wafer 130), a chip-to-wafer electrical connection is provided.

Next, as shown in FIG. 2H, the chip-to-wafer stack formed in the step shown in FIG. 2G is divided into individual chips by dicing. As a result, a plurality of chip-to-chip stacks are formed in each of which one of the plurality of memory chip stacks 104, one of the plurality of interface chips 103, and one of the plurality of logic chips 102 resulting from the division of the third wafer 130 are stacked. Thereafter, each of the chip-to-chip stacks is mounted on the interposer, and packaged with a resin, though not shown, whereby the same semiconductor device as the semiconductor device shown in FIG. 1 is obtainable.

In the method for fabricating the semiconductor device according to the present example embodiment described above, a three-dimensional integrated circuit element is formed by a SiP method using the wafer-to-wafer stacking method and the chip-to-wafer stacking method in combination. Since the plurality of chips are electrically connected to each other with the through-silicon-vias and stacked, increases in package area and package size can be reduced compared with the case where an electrical connection is provided using flip-chip, wire bonding, or the like.

Additionally, in accordance with the method for fabricating a semiconductor device of the present example embodiment, when a large number of chips having identical integrated circuits, such as memory chips, are stacked, the wafer-to-wafer stacking method is used which bonds together the mutually corresponding chips each on a wafer level. Accordingly, compared with the conventional integration method which repeatedly implements the chip-to-chip stacking method a plurality of times, a chip stack can be fabricated with high accuracy by a simple and easy process. Therefore, it is possible to achieve a reduction in fabrication cost and an improvement in fabrication throughput.

Moreover, in accordance with the method for fabricating a semiconductor device according to the present example embodiment, even when chips of different chip sizes are stacked as in the case of stacking a memory chip stack and an interface chip or a logic chip, the chip-to-wafer stacking method is used which bonds together mutually corresponding chips including one on a chip level and the other on a wafer level with a through-silicon-via. Accordingly, compared with the conventional integration method which two-dimensionally arranges the plurality of chips of different chip sizes without stacking them, increases in the package area and package size of the entire three-dimensional integrated circuit element can be reduced. Furthermore, since the chip stack can be fabricated with high accuracy by a simple and easy method compared with that fabricated by the conventional integration method which repeatedly implements the chip-to-chip stacking method a plurality of times, it is possible to achieve a reduction in fabrication cost and an improvement in fabrication throughput.

Note that, in the present example embodiment, the interposer is used for mounting the chip stack, but a resin substrate or the like may also be used instead.

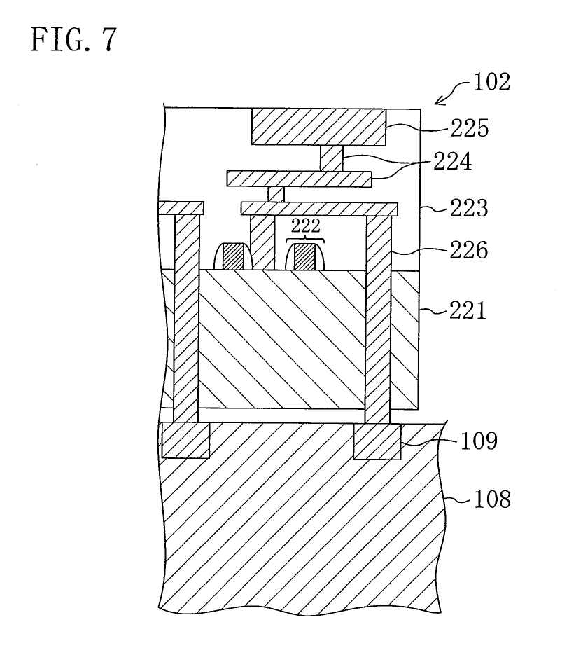

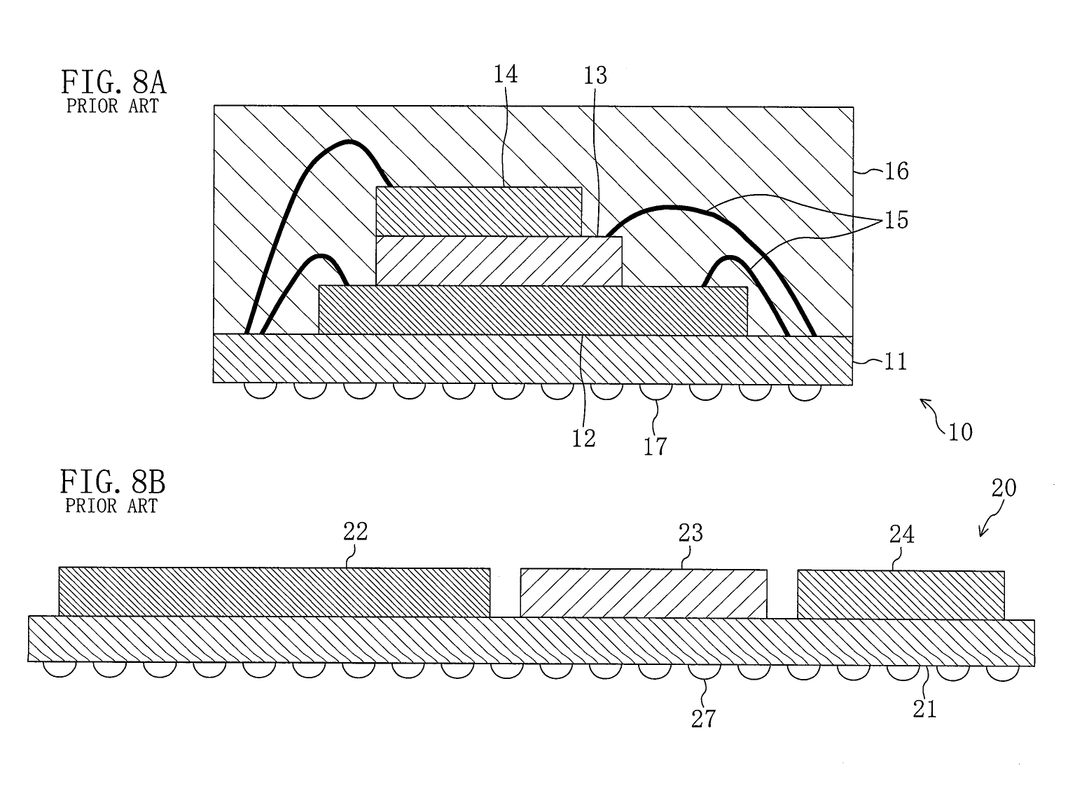

In the present example embodiment, each of the chip-to-chip stacks is formed first by stacking the memory chip stacks 104, the interface chips 103, and the logic chips 102 in the step shown in FIG. 2H, and then mounted on the interposer to be packaged with the resin. Instead, however, it is also possible to stack, after the step shown in FIG. 2H, a chip-to-chip stack in which the memory chip stack 104, the interface chip 103, and the logic chip 102 are stacked and another chip (e.g., another logic chip) 108 to form a chip-to-chip stack, mount the chip-to-chip stack thus formed on an interposer, and then package the chip-to-chip stack with a resin, as shown in FIGS. 6A and 6B. FIG. 7 is a cross-sectional view showing details of a chip-to-chip connection in a chip-to-chip stack formed in the step shown in FIG. 6B. As shown in FIG. 7, in each of the logic chips 102, gate electrode structures 222 are formed on a substrate 221 made of, e.g., silicon. In addition, an interlayer insulating film 223 is formed so as to cover the gate electrode structures 222. In the interlayer insulating film 223, there is formed a multilayer interconnection 224. In a surface portion of the interlayer insulating film 223, there is formed an electrode terminal 225 connected to the multilayer interconnection 224. In the substrate 221 and the interlayer insulating film 223, there is formed a through-silicon-via 226 having one end connected to the multilayer interconnection 224 and the other end reaching the back surface of the substrate 221. By the connection of the other end of the through-silicon-via 226 exposed at the back surface of the substrate 221 to the corresponding one of electrode terminals 109 formed in the surface portion of the chip 108, a chip-to-chip electrical connection is provided.

In the present example embodiment, the memory-chip stack 104 and the interface chip 103 are directly stacked with the through-silicon-via. Instead, however, it is also possible to use a configuration in which the memory chip stack 104 and the interface chip 103 are two-dimensionally arranged at different positions on the logic chip 102. Alternatively, it is also possible to mount another chip, e.g., a MEMS (micro electro mechanical systems) chip on the logic chip 102.

It is appreciated that, in the present example embodiment, the number of chips forming the chip stack and the types thereof are not particularly limited. That is, the gist of the present disclosure is to use, in the formation of the chip stack, at least one of the wafer-to-wafer stacking method that bonds together mutually corresponding chips each on a wafer level and the chip-to-wafer stacking method that bonds together mutually corresponding chips including one on a chip level and the other on a wafer level. It will be appreciated that the present disclosure is not limited to the embodiment described above.

What is claimed is:

1. A method for fabricating a semiconductor device having a three-dimensional integrated circuit formed by stacking at least three or more plurality of chips, comprising the step of:
stacking the plurality of chips using at least two or more of three stacking methods which are a wafer-to-wafer stacking method that bonds together the mutually corresponding chips each on a wafer level, a chip-to-wafer stacking method that bonds together the mutually corresponding chips including one on a chip level and the other on a wafer level, and a chip-to-chip stacking method that bonds together the mutually corresponding chips each on a chip level.

2. The method of claim 1, wherein, when the mutually corresponding chips are bonded together using the wafer-to-wafer stacking method, the chip-to-wafer stacking method, or the chip-to-chip stacking method, the both chips are electrically connected to each other with a through-silicon-via.

3. A method for fabricating a semiconductor device, comprising the steps of:
(a) stacking a plurality of first wafers each provided with a plurality of memory chips so as to electrically connect the mutually corresponding memory chips to each other with first through-silicon-vias to form a wafer stack;
(b) dividing the wafer stack by dicing to form a plurality of first chip-to-chip stacks;
(c) stacking the plurality of first chip-to-chip stacks and a second wafer provided with a plurality of interface chips so as to electrically connect the first chip-to-chip stacks and the interface chips, which correspond to each other, with second through-silicon-vias to form a first chip-to-wafer stack;
(d) dividing the first chip-to-wafer stack by dicing to form a plurality of second chip-to-chip stacks;
(e) stacking the plurality of second chip-to-chip stacks and a third wafer provided with a plurality of logic chips so as to electrically connect the second chip-to-chip stacks and the logic chips, which correspond to each other, via third through-silicon-vias to form a second chip-to-wafer stack; and
(f) dividing the second chip-to-wafer stack by dicing to form a plurality of third chip-to-chip stacks.

4. The method of claim 3, wherein
the step (b) includes the step of fixing the wafer stack onto a support substrate, and dicing the wafer stack, and
the step (c) includes the step of forming the first chip-to-wafer stack, and then stripping the support substrate from the first chip-to-wafer stack.

5. The method of claim 3, further comprising, between the steps (c) and (d), the step of:
polishing the back surface of the second wafer of the first chip-to-wafer stack to thin the second wafer.

6. The method of claim 3, wherein the first through-silicon-vias, the second through-silicon-vias, and the third through-silicon-vias are each formed of a conductive material containing copper as a main component.

7. The method of claim 3, further comprising, after the step (f), the step of:
(g) stacking each of the plurality of third chip-to-chip stacks and each of a plurality of other chips to form a plurality of fourth chip-to-chip stacks.
